(19) United States
(12) Patent Application Publication
(10) Pub. No.: US 2006/0203941 A1
(43) Pub. Date: Sep. 14, 2006

(54) Method and apparatus to establish for imperfect channel state information at a receiver

(76) Inventors: Mohammad Jaber Borran, San Diego, CA (US); Ashutosh Sabharwal, Houston, TX (US); Bahnaam Aazhang, Houston, TX (US)

Correspondence Address: HARRINGTON & SMITH, LLP, 4 RESEARCH DRIVE, SHELTON, CT, 06484-6212, US

(21) Appl. No.: 10/523,167

(22) PCT Filed: May 29, 2003
(86) PCT No.: PCT/IB03/02088

§ 371 Date: Mar. 10, 2006

Related U.S. Application Data
(60) Provisional application No. 60/393,083, filed on Jul. 1, 2002.

(51) Int. Cl. H04L 27/06; H03D 1/04

(52) U.S. Cl. 375/340; 375/346

(57) ABSTRACT

The system and method utilize design criteria and construction for signal constellations in communication systems, such as cellular telephony, that have imperfect channel state information at the receiver. The system and method assume an imperfect knowledge of fading channel state information (600B) and statistics of channel fading (600D) are used to encode additional information into the space-time matrix signal constellation as variations in amplitude of constellation (600E) points. In the preferred embodiment space-time matrix constellations and design criterion are based on the Kullback-Leibler distance between conditional distributions.

### TECHNICAL FIELD

This invention relates generally to design criteria and construction for signal constellations to be used in systems with imperfect channel state information at the receiver. More particularly, this invention relates to using space-time matrix constellations and design criterion based on the Kullback-Leibler distance between conditional distributions.

### BACKGROUND OF THE INVENTION

Wireless communication systems serving stationary and mobile wireless subscribers are currently in wide use and are very popular with consumers. Numerous system layouts and communications protocols have been developed to provide coverage in such wireless communication systems.

The wireless communications channels between the transmit device, or transmission unit, (transmitter) and receive device, or receiver unit, (receiver) are inherently variable. Thus, their quality parameters fluctuate in time. Under favorable conditions, wireless channels exhibit good communication parameters, e.g., large data capacity, high signal quality, high spectral efficiency and throughput. Under these favorable conditions, significant amounts of data can be transmitted via the channel reliably. However, as the channel changes in time, the communication parameters also change. Under altered conditions, former data rates, coding techniques and data formats may no longer be possible. For example, when the channel performance is degraded, the transmitted data may experience excessive corruption yielding unacceptable communication parameters. For instance, transmitted data can exhibit excessive bit-error rates or packet error rates. The degradation of the channel can be due to a multitude of factors such as general noise in the channel, multi-path fading, loss of line-of-sight path, excessive Co-Channel Interference (CCI) and other factors.

In mobile communications systems, a variety of factors may cause signal degradation and corruption. These include interference from other cellular users within or near a particular cell. Another source of signal degradation is multipath fading, in which the received amplitude and phase of a signal varies over time.

In wireless communication systems, channel state information at the receiver is usually obtained through a training sequence. For fast fading channels where the fading coefficients vary too fast to allow a long training period, or for multiple antenna systems where very long training sequences are required to accurately train all of the possible channels from transmitter to receiver, obtaining an accurate estimate of the channel may not always be possible at the receiver. In these instances, where only a rough estimate of the channel state is available at the receiver, existing constellations, which are designed with the assumption of perfect channel state information at the receiver, are not optimal.

PSK (phase shift key) constellations, which are not sensitive to the errors in the estimates of channel amplitude, are usually used in the case of unreliable channel estimates at the receiver. However, for high rate applications, which require larger signal sets, PSK constellations have a very poor performance and are not desirable.

Thus, what is needed to advance the state of the art is an apparatus and method that can provide an acceptable error rate performance, at the required data rates, in the presence of channel estimation errors.

### SUMMARY OF THE PREFERRED EMBODIMENTS

Accordingly, one embodiment of the present invention is directed to a method for establishing a space-time matrix signal constellation. The method includes assuming an imperfect knowledge of fading channel state information. Statistics of channel fading are used to encode additional information into the space-time matrix signal constellation as variations in amplitude of constellation points. The method determines a distance between the constellation points as a function of a Kullback-Leibler distance between conditional distributions.

Another embodiment of the present invention is directed to a symbol detection method that includes obtaining a data sample as a function of a received signal and obtaining channel fading information. A symbol is determined from the data sample and the channel fading information in accordance with a constellation generated in accordance wit this invention.

Yet another embodiment of the present invention is directed to an apparatus for establishing a space-time matrix signal constellation. The apparatus includes means for assuming an imperfect knowledge of fading channel state information, means for using statistics of channel fading to encode additional information into the space-time matrix signal constellation as variations in amplitude of constellation points, and means for determining a distance between the constellation points as a function of the Kullback-Leibler distance between conditional distributions.

Yet another embodiment of the present invention is directed to a computer program, stored on an electronic medium that implements the method described above.

Yet another embodiment of the present invention is directed to a networked device or element that stores the method described above, and further embodiments pertain to wireless communication systems transmitters and receivers that operate in accordance with the symbol constellation generated by the method and apparatus of this invention.

### BRIEF DESCRIPTION OF THE DRAWINGS

FIG. 1 shows a receiver unit according to the present invention.

FIGS. 2A-2D show an 8-point constellation with an average power of 10 for different values of σ²_{E}.

FIGS. 3A-3D show a 16-point constellation with an average power of 10 for different values of σ²_{E.}

FIG. 4 shows a graph of a symbol error rate for an 8-point constellation.

FIG. 5 shows a graph of a symbol error rate for a 16-point constellation.

FIG. 6 shows a high level block diagram of a portion of a receiver that includes a symbol detection block that operates in accordance with this invention, while FIG. 7A is a flowchart showing operation of a transmitter, and FIG. 7B is a flowchart that shows operation of the receiver.

### DETAILED DESCRIPTION OF THE PREFERRED EMBODIMENTS

By way of introduction, an advancement in the state of the art is achieved by the use of space-time matrix constellations that are optimally designed with the consideration of errors in the channel estimate, thereby improving receiver performance in the presence of imperfect channel state information at the receiver. A channel can be a single path or (more typically) a multi-path, either RF or voice, for transmitting electrical signals between a sending point and a receiving point. Channels are often measured in terms of the amount of spectrum they occupy (bandwidth). Constellations, are for example, graphical representations of signal states for a digital system. Selected phase-amplitude pairs are referred to as constellation points. Constellations of the present invention exploit the statistics of the fading to encode additional information in the amplitudes of the transmit signals (as opposed to the PSK constellations in which all of the constellation points have the same amplitude). This allows for additional points in the constellation (higher rate) with a given peak power. In accordance with the teachings of this invention, and assuming the existence of a given signal-to-noise ratio and estimation variance, a multi-level constellation of desired size is designed using a design criteria based on the Kullback-Leibler (KL) distance between conditional distributions.

When a signal is being received, it has to be demodulated in order for the information therein to be detected. However, a signal transferred over the radio path can be distorted in various ways, thus complicating modulation detection. Signal-impairing phenomena include e.g. noise and inter-symbol interference (ISI). A signal-distorting phenomenon also arises when a signal on a radio connection is reflected from various obstacles, such as buildings and irregularities in the terrain. In this case, the signal detected at a receiver is the sum of a plurality of propagation paths. Each propagation path is different in length and signals arrive at the receiver at different points of time, i.e. the delay varies. In addition, the movement of a vehicle causes frequency deviations in relation to speed, the deviations being called Doppler frequencies.

One type of modulation that maybe used is π/4-DQPSK (π/4-shifted. Differential Quaternary Phase Shift Keying modulation). This modulation method comprises eight phase states, but only four phase shifts. Allowed phase shifts (symbols) are ±π/4 and ±3π/4. In practice, the π/4-DQPSK constellation varies at intervals of a symbol between two 4-point constellations. Non-idealities of a channel may cause constellation points to shift.

It is typical of the radio path that a transmitted signal arrives at a receiver along a plurality of propagation paths, each having a specific time delay, channel properties also change as a function of time. For example, beams reflected and delayed on the radio path cause so-called inter-symbol interference (ISI). The frequency response, or impulse response, of a channel can be estimated by the use of a discrete-timed filter channel estimator, whose filter tap coefficients model the radio channel. Such a channel estimator is used to describe the state of a radio channel, and refers generally to a mechanism for estimating and maintaining a description of the complex impulse response of a radio channel.

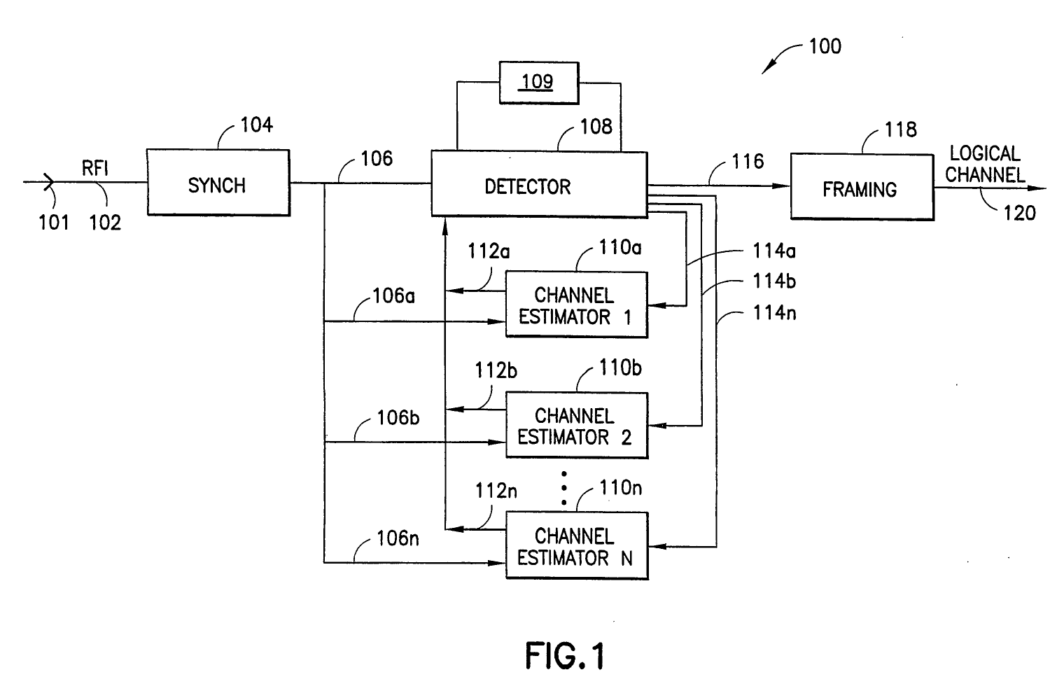

FIG. 1 shows a receiver 100 that may be used with the present invention. This receiver is typically part of a cellular telephone, which has sufficient memory to store signal constellations as look-up tables in the telephone handset, or that may retrieve signal constellations that are stored at a transmitter location, such as a base unit location, or, in general, that are stored in any memory that is accessible via a wireless network. The receiver 100 may be used in many cellular telephone applications, one non-limiting example being a cdma2000 cellular telephone system (or evolutions thereof). Upon reception, a signal is received from a transmitter to an antenna 101 and radio-frequency parts (not shown) process the signal. Samples are then taken with an A/D converter (not shown) from an intermediate-frequency signal. The samples are applied to a synchronization module, or unit, 104. The synchronization module 104 searches the obtained samples for the training sequence associated with the frame structure and uses it to accurately determine the sampling moment, i.e. locations of all symbols in the sample flow. The synchronization module 104 also controls the radio-frequency parts of the receiver so as to maintain a signal arriving at the AND converter at an optimal level (AND converter not shown). The synchronization module 104 applies the frame to a channel detector module, or unit, 108.

When information is transferred on a radio channel, the signal to be transmitted has to be subjected to modulation. Modulation converts the signal into a form in which it can be transmitted at radio frequency. A modulation method can be considered efficient, for instance, if it allows as much information as possible to be transferred using as narrow a frequency band as possible. Depending on the purpose of use, other features can also be emphasized. Modulation should also cause as little interference as possible to adjacent channels. The channel detector module 108 includes, or is suitably coupled to, a memory 109. The detector module 108 uses an algorithm to detect the transmitted symbols as a function of assumed imperfect knowledge of fading channel state information.

The detector module 108 is coupled to at least one adaptive channel estimator module or unit 110(a) . . . (n), where n is any suitable integer number. The channel estimators 110 receive input from the synchronization module 104 via associated interconnectors 106(a) . . . (n), respectively. Interconnectors 106 are typically wires, or wireless transmission means that are adapted to transmit data. The detector module 108 receives as inputs, outputs from the estimators, generally 110 via associated interconnectors 112(a) . . . (n), respectively. Detector module 108 outputs information to estimator modules 110, via associated interconnectors 114(a) . . . (n), respectively. Interconnectors 112 and 114 are similar to interconnectors 106 described herein. Detector module 108 utilizes an algorithm or stored program to demodulate the received signal and compare the demodulated signal to one or more space-time matrix signal constellations, which are typically stored in a memory, such as a look-up table, either in the mobile phone handset (also referred to as a mobile station, such as a cellular telephone), in a transmitter, at a base station or at a location accessible via a wireless network. A logical channel 120 is formed from the framing unit 118.

An example of the general structure of a receiver has been described to facilitate understanding the present invention. However, the structure of the receiver may change without deviating from the present invention, which is directed to a channel equalizer/detector of a receiver.

It should be noted that the performance gain realized by the present invention becomes substantial as the number of receive antennas increases, which implies that the present invention may be particularly useful for uplink (mobile station to base station) communication. However, the teachings of this invention provide significant performance enhancements when used in the downlink direction as well, i.e., when implemented in the mobile station. It should be further noted that a significant improvement in performance is also achieved when the improved signal constellations are used in conjunction with an outer error correcting code. For example, the outer code may be a block or a trellis code designed to encode several signal matrices across time. By designing the outer code based on the Kullback-Leibler (KL) distance criterion, the minimum distance between coded blocks can be further increased, and hence improved error rate performance can be realized.

Design criterion is derived for the very general case of matrix constellations (to be used with multiple transmit antennas over several symbol intervals). Therefore, additional improvements in the performance are obtained when the channel remains constant, or almost constant, for several symbol intervals, and/or if multiple transmit antennas are available.

The present invention has application to digital communication in, for example, a Rayleigh flat fading environment using a multiple antenna system. Rayleigh fading is a type of signal fading caused by independent multipath signals having a Rayleigh PDF.

In order to set the parameters of the present invention, it is assumed that the transmitter does not know the channel coefficients, and that the receiver has only an estimate of them with some known estimation variance. Utilizing the Kullback-Leibler (KL) distance between conditional distributions as a performance criterion, a design criterion can be derived based on maximizing the minimum KL distance between constellation points. As an example, constellations may be designed for a single transmit antenna system using the above criterion, and the newly derived constellations can provide a substantial improvement in the performance over existing constellations.

For example, consider a communication system with M transmit and N receive antennas in a block Rayleigh flat fading channel with coherence interval of T symbol periods (i.e., assume that the fading coefficients remain constant during blocks of T consecutive symbol intervals, and change to new, independent values at the end of each block). The following complex baseband notation may be used:
X=SH+W, (1)
where S is the T×M matrix of transmitted signals with power constraint Σₜ₌₁^{T}Σₘ₌₁^{M}E{|sₜₘ|²}=TP, where the sₜₘ's are the elements of the signal matrix S, X is the T×N matrix of received signals, H is the M×N matrix of fading coefficients, and W is the T×N matrix of the additive received noise. Elements of H and W are assumed to be statistically independent, identically distributed circular complex Gaussian random variables from the distribution CN(0,1). It can also be assumed that H=Ĥ+\tilde{H}, where Ĥ is known to the receiver but \tilde{H} is not. Furthermore, it can be assumed that \tilde{H} has i.i.d. elements from CN(0,σ_{E}²), and is statistically independent from Ĥ (this can be obtained, e.g., by using an LMMSE estimator).

With the above parameters, the conditional probability density of the received signal can be written as:

$$p ( X \vert S , \hat{H} ) = {E}_{\tilde{H}} \{ p ( X \vert S , \hat{H} , \tilde{H} ) \} = \frac{\begin{matrix}exp \{ - tr [ {( {I}_{T} + {σ}_{E}^{2} {SS}^{H} )}^{- 1} \\ ( X - S \hat{H} ) {( X - S \hat{H} )}^{H} ] \}\end{matrix}}{{π}^{TN} {det}^{N} ( {I}_{T} + {σ}_{E}^{2} {SS}^{H} )} \qquad ( 2 )$$

Assuming a signal set of size L, {Sᵢ}ᵢ^{L}=₁, and defining pi(X)=p(X|Si,Ĥ), the Maximum Likelihood (ML) detector for this system has the following form:

$${\hat{S}}_{ML} = {S}_{{\hat{l}}_{ML}} , where {\hat{l}}_{ML} = arg {max}_{l ∈ \{ 1 , … L \}} {p}_{l} ( X ) \qquad ( 3 )$$

If L=2, then the probability of error in ML detection of S₁ (detecting S₂ given that S₁ was transmitted) is given by:
Pr(S₁→S₂)=Pr{p₂(X)>p₁(X) |S₁} (4)

For L>2, even though equation (4) is no longer exact, it may still be used as an approximation for the pairwise error probability. The average error probability of the ML detector, which is obtained by averaging the pairwise error probabilities over the signal set, is usually dominated by the largest term, i e., the maximum of equation (4) over the signal set. Therefore, as in at least some other constellation/code design techniques, the maximum of equation (4) over the signal set may be used as the performance criterion, and optimal constellations may be identified by minimizing it over all possible constellations of the given size. Unfortunately, the exact expression, or even the Chernoff bound for equation (4), in general, seems to be intractable. Therefore, according to Stein's lemma, the Kullback-Leibler (KL) distance between distributions (which is an upper bound on the rate of exponential decay of pairwise error probability), is used instead as the performance criterion. The KL quantity of information (Kullback-Leibler quantity) is one known reference for measuring the distance between a model and a true distribution when predicting the true probability distribution from given data.

The optimal constellations are then obtained by searching for signal sets which have the largest minimum KL distance.
Using equation (2), the KL distance between pᵢ and pⱼ can be calculated as:

$$D ( {p}_{i} ‖ {p}_{j} ) = Ntr \{ ( {I}_{T} + {σ}_{E}^{2} {S}_{i} {S}_{i}^{H} ) {( {I}_{T} + {σ}_{E}^{2} {S}_{j} {S}_{j}^{H} )}^{- 1} \} - NT - N ln det \{ ( {I}_{T} + {σ}_{E}^{2} {S}_{i} {S}_{i}^{H} ) {( {I}_{T} + {σ}_{E}^{2} {S}_{j} {S}_{j}^{H} )}^{- 1} \} + N ln det \{ {I}_{M} + ( 1 - {σ}_{E}^{2} ) {( {S}_{i} - {S}_{j} )}^{H} {( {I}_{T} + {σ}_{E}^{2} {S}_{j} {S}_{j}^{H} )}^{- 1} ( {S}_{i} - {S}_{j} ) \} \qquad ( 5 )$$

In the two extreme cases of σ_{E}²=0 and σ_{E}²=1, equation (5) reduces to the existing performance criteria for coherent and non-coherent space-time codes. A coherent space-time code implies that the multi-level signal constellation is designed for the case of σ_{E}²=0, i.e., perfect channel state (phase and amplitude) information is assumed to be known at the receiver. In contrast, the non-coherent space time code assumes the case of σ_{E}²=1, i.e., no channel state information is assumed to be known at the receiver. For σ_{E}²=0 (perfect channel state information at the receiver, i.e. coherent communication), equation (5) reduces to:
D(pᵢ∥pⱼ)=Nln det{I_{M}+(Sᵢ−Sⱼ)^{H}(SᵢSⱼ)}, (6)
which is the same performance criterion given by V. Tarokh, N. Seshadri, and A. R. Calderbank, “Space-time codes for high data rate wireless communication: Performance criterion and code construction”, IEEE Transactions on Information Theory, vol. 44, no. 2, pp. 744-765, March 1998, for coherent space-time codes, and results in the rank and determinant design criteria. The rank and determinant design criteria are used to design space-time codes for systems with perfect channel state information at the receiver. For the case of σ_{E}²=1 (no channel state information at the receiver, i.e. non-coherent communication), equation (5) reduces to:
D(pᵢ∥pⱼ)=Ntr{(I_{T}+SᵢS₁^{H})(I_{T}+SⱼSⱼ^{H})⁻¹}−NT−Nln det{(I_{T}+SᵢSᵢ^{H})(I_{T}+SⱼSⱼ^{H})⁻¹}, (7)
which is the same performance criterion given by M. J. Borran, A. Sabharwal, B. Aazhang, and D. H. Johnson, “On design criteria and construction of non-coherent space-time constellations”, in Proceedings of the IEEE International Symposium on Information Theory, July 2002, for non-coherent space-time codes. For the intermediate values of σ_{E}², the performance criterion is a combination of the two extreme values, reflecting the fact that, for an optimal design, contributions from both of the extreme performance criteria should be considered to achieve improved performance.

Adopting the KL distance as the performance criterion, the signal set design can be formulated as the following optimization problem:

$${Maximize}_{1 / L {\sum }_{l = 1}^{L} {‖ {S}_{l} ‖}^{2} = TP} {min}_{i \neq j} D ( {p}_{i} ‖ {p}_{j} ) , \qquad ( 8 )$$

where ∥Sₗ∥²=Σₜ₌₁^{T}Σₘ₌₁^{M}|(Sₗ)ₜₘ|² is the total power used to transmit Sᵢ. Since the actual value of N does not affect the maximization in equation (8), in designing the optimal signal sets, it may always be assumed that N=1.

In order to demonstrate the design technique of the present invention and the effect of channel estimation error in the structure of resulting constellations, it is helpful to consider the simple case of a single transmit antenna system in a fast fading environment. In this case, M=1 and T=1, so each Sᵢ, is simply a complex scalar. The expression for KL distance in equation (5) reduces to:

$${D}_{1} \text{(} {p}_{i} ‖ {p}_{j} ) = \frac{1 + {\vert {s}_{i} \vert}^{2}}{1 + {\vert {s}_{j} \vert}^{2}} - 1 - ln ( \frac{1 + {\vert {s}_{i} \vert}^{2}}{1 + {\vert {s}_{j} \vert}^{2}} ) + ln [ 1 + ( 1 - {σ}_{E}^{2} ) \frac{{\vert {s}_{i} - {s}_{j} \vert}^{2}}{1 + {σ}_{E}^{2} {\vert {s}_{j} \vert}^{2}} ] \qquad ( 9 )$$

Using the concept of multilevel unitary (circular, in this case) constellations, constellations containing points on concentric circles are considered, and the optimization problem is solved to find the optimum values for the number of circles, their radiuses, and the number of constellation points on each circle. It can be shown that the actual minimum KL distance of the resulting constellations will be greater than or equal to the one guaranteed by this approach, whereas the number of the parameters of the simplified optimization problem is much smaller than the complete problem.

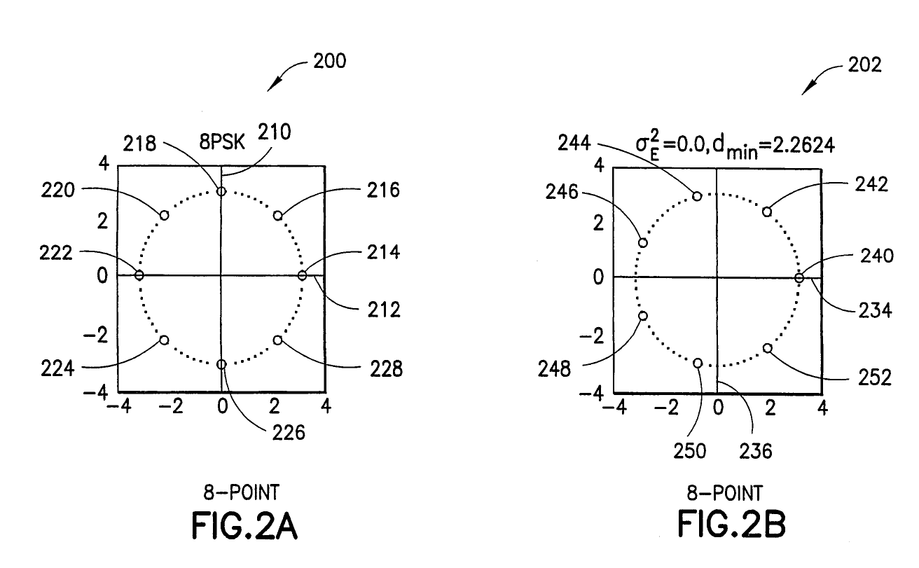

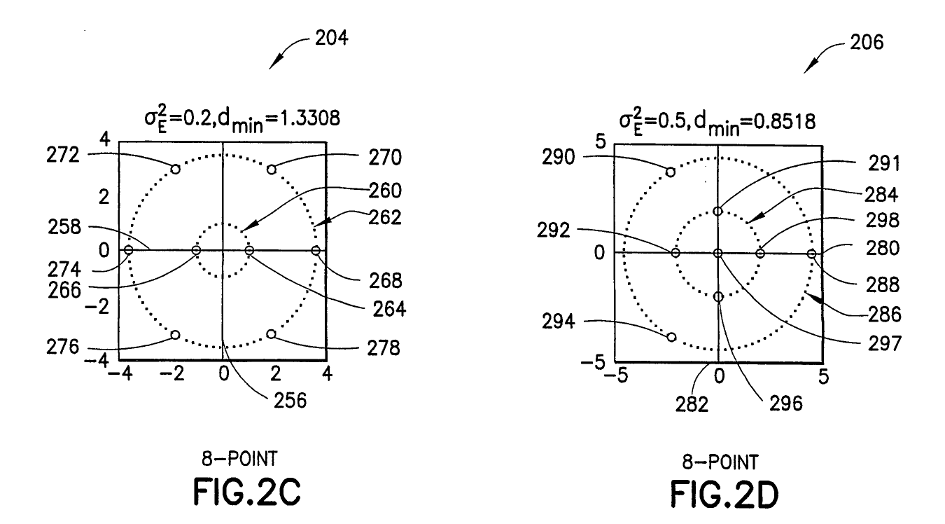

FIGS. 2A-D show optimal constellations of size 8 for M=1,T=1, Pₐᵥ=10, and different values of σ_{E}². These constellations are typically stored in a memory located at the mobile handset unit, transmitter unit, base unit or memory location accessible via a wireless network.

FIG. 2A shows a signal constellation 200 plotted on vertical axis 210 and horizontal axis 212. Constellation points 214, 216, 218, 220, 222, 224, 226 and 228 indicate the phase and magnitude for an 8-PSK constellation. As shown by FIG. 2A, points 214, 218, 222 and 226 are each positioned on an axis. Point 220 is positioned in a first quadrant, point 226 is positioned in a second quadrant, point 228 is positioned in a third quadrant and point 224 is positioned in a fourth quadrant.

FIG. 2B shows a signal constellation 202 for an 8-point constellation in which σ_{E}² is 0.0 and dₘᵢₙ is 2.2624 (dₘᵢₙ is an absolute number having no units). The constellation is plotted on horizontal axis 234 and vertical axis 236 and includes constellation points 240, 242, 244, 246, 248, 250 and 252.

FIG. 2C shows a signal constellation 204 for an 8-point constellation in which σ_{E}² is 0.2 and dₘᵢₙ is 1.3318. The constellation is plotted on horizontal axis 258 and vertical axis 256. Constellation points 268, 270, 272, 274, 276 and 278 form a first signal configuration 262. Constellation points 264 and 266 form a second signal configuration 260. Signal configuration 260 is closer to the origin than signal configuration 262 and signal configurations 260 and 262 form substantially concentric circles.

FIG. 2D shows a constellation 206 for an 8-point constellation in which σ_{E}² is 0.5 and dₘᵢₙ is 0.8518. The constellation is plotted on horizontal axis 280 and vertical axis 282. Constellation points 288, 290, and 294 form signal configuration 286. Constellation points 291, 292, 296 and 298 form signal configuration 284. Point 297 is positioned at the origin. Signal configurations 284 and 286 form substantially concentric circles.

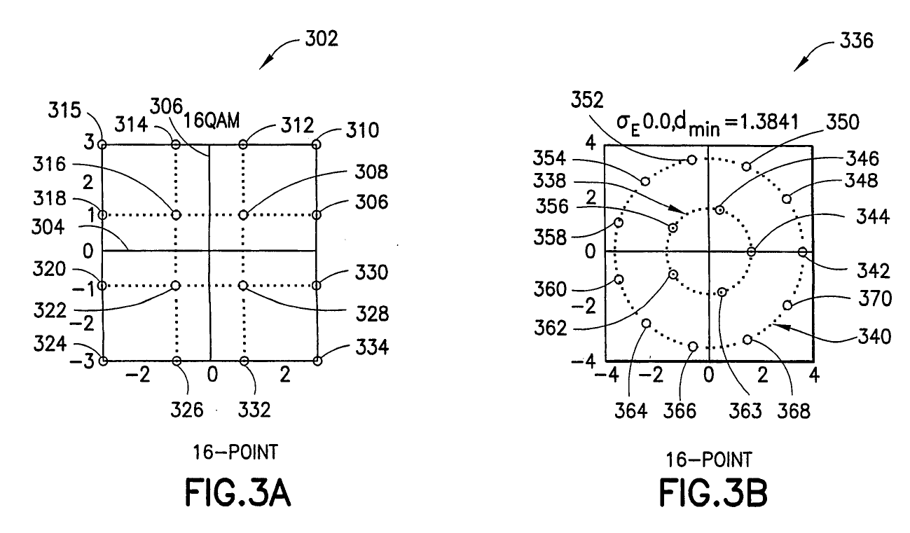

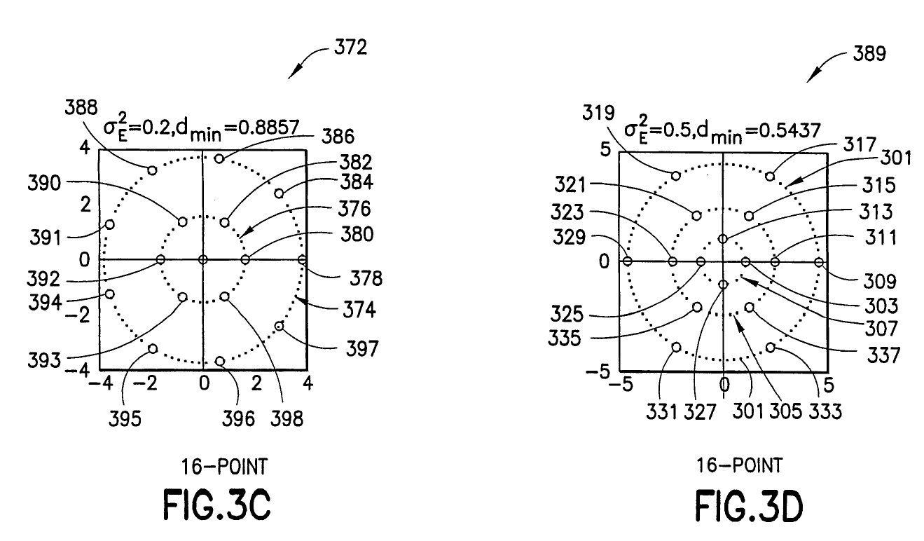

FIGS. 3A-D show optimal constellations of size 16 for M=1, T=1, Pₐᵥ=10, and different values of σ_{E}².

FIG. 3A shows a 16-QAM signal constellation 302 plotted on vertical axis 306 and horizontal axis 304. Constellation points 314, 315, 316 and 318 are positioned in a first quadrant. Constellation points 306, 308, 310 and 312 are positioned in a second quadrant. Constellation points 328, 330, 332 and 334 are positioned in a third quadrant and constellation points 320, 322, 324 and 326 are positioned in a fourth quadrant.

FIG. 3B shows a 16-point constellation 336 in which σ_{E}² is 0.0 and dₘᵢₙ is 1.5841. The figure shows a first constellation configuration 338 that includes constellation points 344, 346, 356, 362 and 363. A second constellation configuration 340 includes constellation points 342, 348, 350, 352, 354, 358, 360, 364, 366, 368 and 370. Constellation configuration 338 is closer to the origin than constellation configuration 340.

FIG. 3C shows a 16-point constellation 372 in which σ_{E}² is 0.2 and dₘᵢₙ is 0.8857. The figure shows a first constellation configuration 376 that includes constellation points 380, 382, 390, 392, 393 and 398. A second constellation configuration 374 includes constellation points 378, 384, 386, 388, 391, 394, 395, 396 and 397. Constellation point 399 is positioned at the origin. Constellation configuration 376 is closer to the origin than constellation configuration 374. Constellation configurations 376 and 374 form substantially concentric circles.

FIG. 3D shows a 16-point constellation 389 in which σ_{E}² is 0.5 and dₘᵢₙ is 0.5437. A first constellation configuration 307 includes constellation points 303, 313, 325 and 327. A second constellation configuration 305 includes constellation points 311, 315, 321, 323, 335 and 337. A third constellation configuration 301 includes constellation points 309, 317, 319, 329, 331 and 333. The first constellation configuration 307 is closest to the origin, and forms a substantially circular shape about the origin. Constellation configurations 305 and 301 form concentric circles, as shown in FIG. 3D.

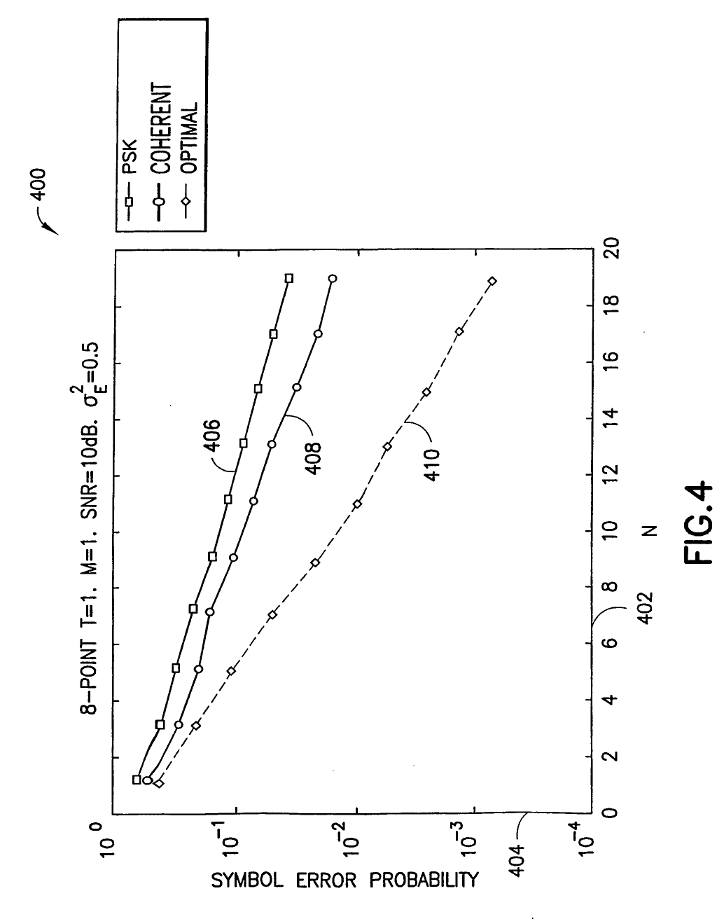

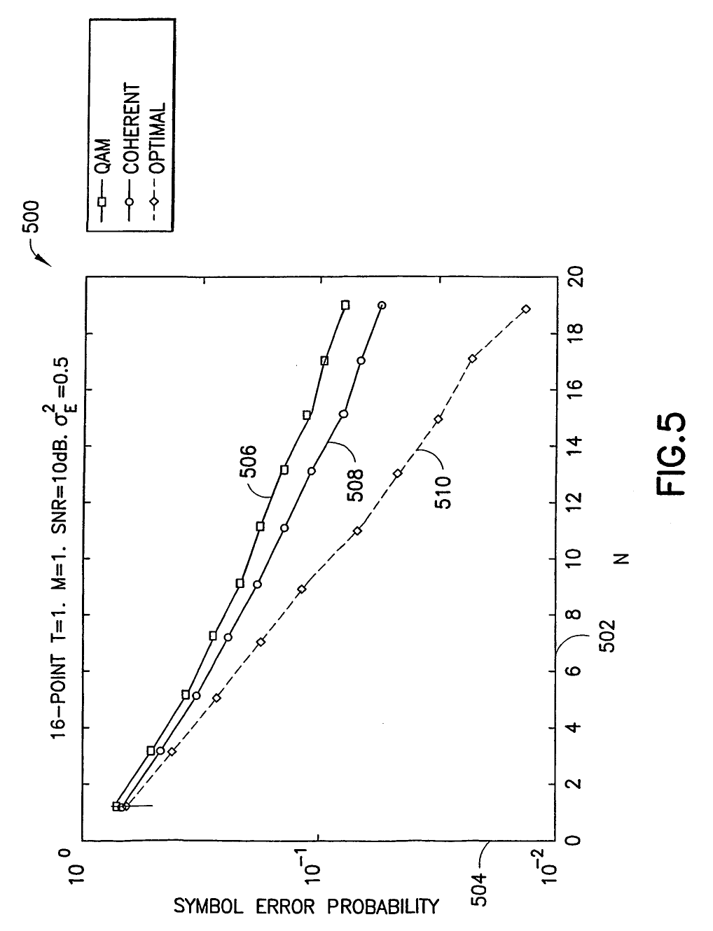

FIG. 4 shows a symbol error rate for constellations of size 8 for M=1, T=1, SNR=10 dB, and σ_{E}²=0.5. The symbol error rate performance of the 8-point constellations at σ_{E}²=0.5 are calculated for different values of N. Graph 400 shows the magnitude of N is plotted on the horizontal axis 402 and the magnitude of the symbol error probability plotted on the vertical axis 404. Line 406 represents the values for a PSK constellation, line 408 represents the values for a coherent constellation and line 410 represents the values for optimal constellations.

FIG. 5 shows a symbol error rate for constellations of size 16 for M=1, T=1, SNR=10 dB, and σ_{E}²=0.5. The symbol error rate performance of the 16-point constellations at σ_{E}²=0.5 are calculated for different values of N. Graph 500 shows the magnitude of N is plotted on the horizontal axis 502 and the magnitude of the symbol error probability is plotted on the vertical axis 504. Line 508 represents the values for a QAM constellation, line 506 represents the values for a coherent constellation and line 510 represents the values for optimal constellations.

The results are shown in FIGS. 4 and 5, where by coherent, it is meant the multilevel circular constellations designed for σ_{E}²=0. Due to the larger minimum KL distance of the optimal constellations the exponential decay rate of the symbol error rate vs. N is significantly greater than for conventional constellations. It is also interesting to notice that at σ_{E}²=0.5, the 16QAM constellation has better performance as compared to the multilevel circular constellation designed for coherent communication. The reason is that 16QAM, if considered as a multilevel circular constellation, is in fact a three level constellation as compared to the coherent constellation, which has only two levels. This is not the case for the 8-point constellations, where the coherent constellation (with two levels) still performs better at σ_{E}²=0.5 than 8PSK (with only one level).

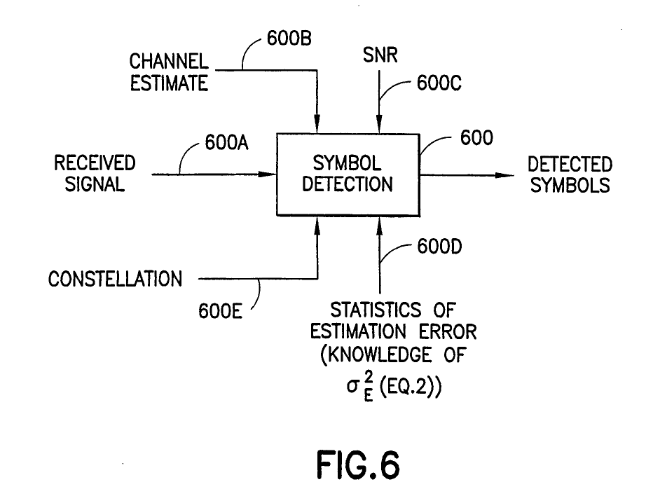

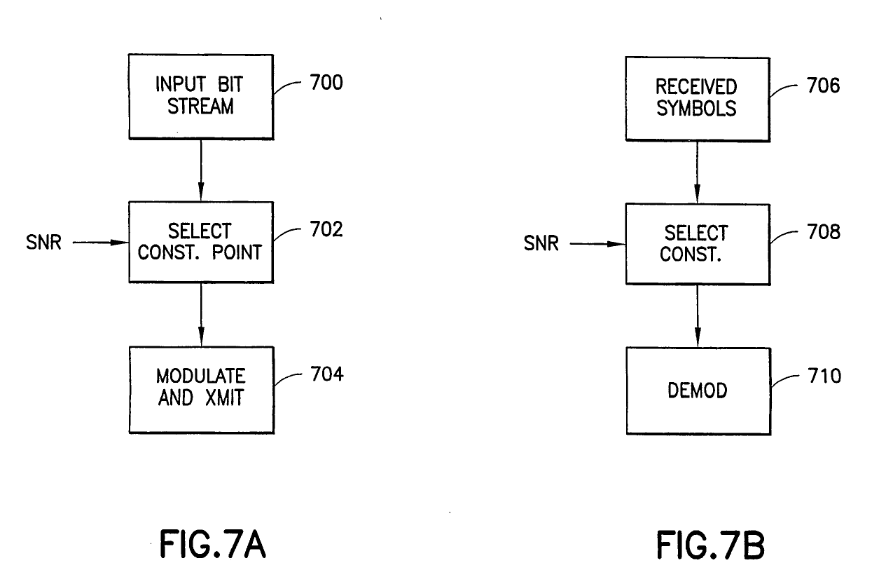

FIG. 6 shows a high level block diagram of a portion of a receiver that includes a symbol detection block 600. Inputs to the symbol detection block 600 include the received signal 600A, a channel estimate 600B, the SNR 600C, the statistics of estimation error 600D (knowledge of σ_{E}²) in accordance with Equation 2 above, and a constellation 600E that was previously constructed, in accordance with this invention, to include amplitude encoded information based on a fading channel that exploits the statistics of the fading process and the channel estimation error. An output of the block 600 is a stream of detected symbols 600F. In FIG. 6 the constellation input 600E may be selected from one of n stored constellation sets, where n may have a value (typically) in the range of about three to about four representing 3-4 SNR ranges. Each constellation set may comprise from a few to several hundred points.

FIG. 7A shows a flowchart of a transmit method. At block 700 a bit stream is inputted, at block 702 a constellation point is selected based on the current SNR, and at block 704 the carrier is modulated in phase, and amplitude, in accordance with the selected constellation point and a symbol corresponding to the inputted bits is transmitted. The current SNR may be made known to the transmitter based on the operation of a power control sub-system, and can be indicated by the receiver through a feedback power control channel.

FIG. 7B shows a flowchart of a receive method. At block 706 a symbol is received from the transmitter of FIG. 7A, at block 708 a constellation is selected based at least on the current SNR, and at block 710 the carrier is demodulated, preferably by Maximum Likelihood (ML) demodulation, based on the selected constellation, and hard symbols or soft bits are output, depending on whether the received symbols are coded or uncoded.

The constellations used in the present invention may, for example, be implemented as lookup tables in either the transmitter unit and/or the receiver unit. The ML decoding (detection) can be done in two stages of “point in subset decoding” and “subset decoding”, similar to trellis coded modulation schemes. That is, given the received signal, first for each sub-set the best point (the point with the largest likelihood, i.e., the point closest to the received signal) is found by calculating the phase of the received signal and quantizing it (point in sub-set decoding). Next, the likelihoods of the best points in different sub-sets are compared to one another to determine the point having the largest likelihood (sub-set decoding).

The present invention has been described in relation to the general structure of a receiver and a transmitter to facilitate understanding the invention. However, the structure of the receiver and/or transmitter may change without deviating from the present invention. In addition, it should be appreciated that the receiver may use any suitable channel estimation scheme.

Furthermore, it should be appreciated that in a communication system apparatus that receives data transmitted by the transmitter of FIG. 7A, the receiver may employ conventional coherent demodulation (a coherent detector) and still obtain a performance increase. Alternatively, the receiver may use an optimal demodulator according to the likelihood function found in Equation (2).

While the Applicants have attempted to describe all of the possible embodiments that the Applicants have foreseen, there may be unforeseeable and insubstantial modifications that remain, and these are considered to be equivalents to the disclosed embodiments.

What is claimed is:

1. A method for establishing a space-time signal constellation, comprising:
assuming an imperfect knowledge of fading channel state information; and
using statistics of channel fading to encode additional information into the space-time signal constellation as variations in amplitude of constellation points.

2. The method as claimed in claim 1, wherein a design criterion for constructing the constellation is the Kullback-Leibler distance between conditional distributions.

3. The method as claimed in claim 1, further comprising:
establishing a plurality of the space-time constellations based on a plurality of signal to noise ratio ranges.

4. The method as claimed in claim 1 further comprising:
storing information descriptive of the signal constellation in a look-up table.

5. The method as claimed in claim 1, further comprising:
storing information descriptive of the signal constellation in a lookup table at a transmitter location.

6. The method as claimed in claim 1, further comprising:
storing information descriptive of the signal constellation in a lookup table at a receiver location.

7. The method as claimed in claim 1, further comprising:
varying an amplitude of a transmit signal according to constellation data.

8. The method as claimed in claim 1, further comprising:
generating the space-time signal constellation for a single transmit antenna system.

9. The method as claimed in claim 1, further comprising:
identifying one or more signal constellation points that have a particular minimum Kullback-Leibler distance; and
generating the signal constellation as a function of the identifying step.

10. The method as claimed in claim 1, further comprising:
establishing additional points in the space-time matrix signal constellation having a particular peak magnitude.

11. A symbol detection method comprising:
obtaining a data sample as a function of a received signal;
obtaining channel fading information; and
determining a signal constellation from the data sample and the channel fading information.

12. The method as claimed in claim 11, wherein the signal constellation includes signal constellation points and a distance between the signal constellation points is a function of a Kullback-Leibler distance between signal constellation points.

13. A computer program, stored on a computer-readable medium, for establishing a space-time signal constellation comprising:
program code, responsive to an assumption of imperfect knowledge of fading channel state information, for using statistics of channel fading to encode additional information into a space-time signal constellation as variations in amplitude of constellation points.

14. The computer program as claimed in claim 13, further comprising:
program code for determining a distance between the constellation points as a function of a Kullback-Leibler distance between conditional distributions.

15. An electronic storage medium that stores a space-time signal constellation generated by:
assuming an imperfect knowledge of fading channel state information; and
using statistics of channel fading to encode additional information into the space-time matrix signal constellation as variations in amplitude of constellation points.

16. The electronic storage medium as claimed in claim 15, where the stored signal constellation is further generated by:
determining a distance between the constellation points as a function of a Kullback-Leibler distance between conditional distributions.

17. A wireless communications system network element comprising storage means for storing a digital representation of at least one signal constellation constructed by assuming an imperfect knowledge of fading channel state information and by using statistics of channel fading to encode additional information into the signal constellation as variations in amplitude of constellation points, where a distance between the constellation points is determined a function of a Kullback-Leibler distance between conditional distributions.

18. The network element as claimed in claim 17, where the network element comprises a part of a base station.

19. The network element as claimed in claim 17, where the network element comprises a part of a mobile station.

20. The network element as claimed in claim 17, where the network element comprises part of a receiver symbol detector.

21. The network element as claimed in claim 17, where the network element comprises part of a transmitter symbol modulator.

22. An apparatus for establishing a space-time matrix signal constellation, comprising:
means for assuming an imperfect knowledge of fading channel state information; and
means for using statistics of channel fading to encode additional information into the space-time matrix signal constellation as variations in amplitude of constellation points.

23. The apparatus as claimed in claim 22, further comprising:
means for determining a distance between the constellation points as a function of a Kullback-Leibler distance between conditional distributions.

24. A communication system apparatus for transmitting data using a space-time matrix signal constellation designed based on a Kullback-Leibler distance criterion and by taking into account inaccuracies in a receiver channel estimator.

25. A communication system apparatus for receiving data transmitted by the transmitter of claim 24, said receiver using coherent demodulation.

26. A communication system apparatus for receiving data transmitted by the transmitter of claim 24, said receiver apparatus using an optimal demodulator according to a likelihood function given by:
$$\begin{matrix}p ( X \vert S , \hat{H} ) = {E}_{\tilde{H}} \{ p ( X \vert S , \hat{H} , \tilde{H} ) \} \\ = \frac{exp \{ - tr [ {( {I}_{T} + {σ}_{E}^{2} {SS}^{H} )}^{- 1} ( X - S \hat{H} ) {( X - S \hat{H} )}^{H} ] \}}{{π}^{TN} {det}^{N} ( {I}_{T} + {σ}_{E}^{2} {SS}^{H} )} ,\end{matrix}$$
where the communication system has M transmit and N receive antennas in a Rayleigh flat fading channel with a coherence interval of T symbol periods, where:
X=SH+W,
where S is the T×M matrix of transmitted signals with power constraint Σₜ₌₁^{T}Σₘ₌₁^{M}E{|sₜₘ|²}=TP, where the sₜₘ's are the elements of the signal matrix S, X is the T×N matrix of received signals, H is the M×N matrix of fading coefficients, and W is the T×N matrix of the additive received noise, where elements of H and W are assumed to be statistically independent, identically distributed circular complex Gaussian random variables from the distribution CN(0,1), and where it is assumed that H=Ĥ+\tilde{H}, where Ĥ is known to the receiver but \tilde{H} is not.
